(19) United States
(12) Patent Application Publication
(10) Pub. No.: US 2017/0271505 A1
(43) Pub. Date: Sep. 21, 2017

(54) N-TYPE LATERAL DOUBLE-DIFFUSED METAL-OXIDE-SEMICONDUCTOR FIELD-EFFECT TRANSISTOR

(71) Applicant: CSMC TECHNOLOGIES FAB1 CO., LTD., Jiangsu (CN)

(72) Inventors: Xiaolong HU, Jiangsu (CN); Guangsheng ZHANG, Jiangsu (CN); Peng BIAN, Jiangsu (CN); Sen ZHANG, Jiangsu (CN)

(73) Assignee: CSMC TECHNOLOGIES FAB1 CO., LTD., Jiangsu (CN)

(21) Appl. No.: 15/320,589

(22) PCT Filed: Jul. 31, 2015
(86) PCT No.: PCT/CN2015/085693

§ 371 Date: Dec. 20, 2016

(30) Foreign Application Priority Data
Dec. 2, 2014 (CN) 201410724508.6

(51) Int. Cl. H01L 29/78; H01L 29/40; H01L 29/49; H01L 29/10

(52) U.S. Cl. CPC H01L 29/7816; H01L 29/7831; H01L 29/1083; H01L 29/1095; H01L 29/408; H01L 29/4916

(57) ABSTRACT

An N type lateral double-diffused metal oxide semiconductor field effect transistor (200) includes a substrate (202); a first N well (204) formed on the substrate; a second N well (206), a first P well (208), a third N well (210) and a fourth N well (212); a source lead-out region (214) formed on the first P well (208); a drain lead-out region (216) formed on the fourth N well (212); a first gate lead-out region formed on surfaces of the second N well (206) and the first P well (208); and a second gate lead-out region formed on surfaces of the first P well (208) and the third N well (210). The first gate lead-out region and the second gate lead-out region are respectively led out by means of metal wires, and then are connected to serve as a gate.

### FIELD OF THE INVENTION

The present invention relates to a technical field of semiconductor manufactures, and more particularly relates to an N type lateral double-diffused metal oxide semiconductor field effect transistor.

### BACKGROUND OF THE INVENTION

The power field effect transistors mainly include two types: a vertical double-diffused field effect transistor (Vertical Double-Diffused MOSFET, VDMOS) and a lateral double-diffused field effect transistor (Lateral Double-Diffused MOSFET,LDMOS). Compared to the VDMOS, the LDMOS possesses many advantages. FIG. 1 is a perspective view of a conventional N type lateral double-diffused metal oxide semiconductor field effect transistor, in which P-sub represents a P type substrate: Deep N represents a deep N well; P-well represents a P well; N-well represents a N well; HV-well represents a high voltage N well; S represents a source, G represents a gate, D represents a drain. However, in the conventional lateral double-diffused metal oxide semiconductor field effect transistor, when the drain thereof is connected to a high voltage, the carrier can only flow from the high voltage N well to the drain, such that when the N type lateral double-diffused metal oxide semiconductor field effect transistor is on a conducting state, the working current is relative low, the current output capability is poor.

### SUMMARY OF THE INVENTION

Accordingly, it is necessary to provide an N type lateral double-diffused metal oxide semiconductor field effect transistor with a greater current output capability.

An N type lateral double-diffused metal oxide semiconductor field effect transistor includes:
a substrate;
a first N well formed on the substrate;
a second N well, a first P well, a third N well, and a fourth N well all of which are formed on a surface of the first N well; wherein the first P well is connected to the second N well and the third N well, respectively: the third N well is connected to the fourth N well;
a source lead-out region formed on the first P well;
a drain lead-out region formed on the fourth N well;
a first gate lead-out region formed on surfaces of the second N well and the first P well; and
a second gate lead-out region formed on surfaces of the first P well and the third N well;
   wherein the first gate lead-out region and the second gate lead-out region are respectively led out by means of metal wires, and the first gate lead-out region and, the second gate lead-out region are connected to serve as a gate of the N type lateral double-diffused metal oxide semiconductor field effect transistor.

Above described N type lateral double-diffused metal oxide semiconductor field effect transistor is provided with a first gate lead-out region and a second gate lead-out region, i.e. a gate lead-out region is added to the source terminal, thereby forming a new current channel by the second N well and the first N well, which enables the current capacity to be doubled, and the current output capacity is relative greater while the area of the device almost does not increase.

### BRIEF DESCRIPTION OF THE DRAWINGS

In order to illustrate the technical solution of the invention or prior art more clearly, hereinafter, a brief introduction of accompanying drawings employed in the description of the embodiments or the prior art is provided. It is apparent that accompanying drawings described hereinafter merely are several embodiments of the invention. For one skilled in the art, other drawings can be obtained according to the accompanying drawings, without a creative work.

FIG. 1 is a perspective view of a conventional N type lateral double-diffused metal oxide semiconductor field effect transistor; and

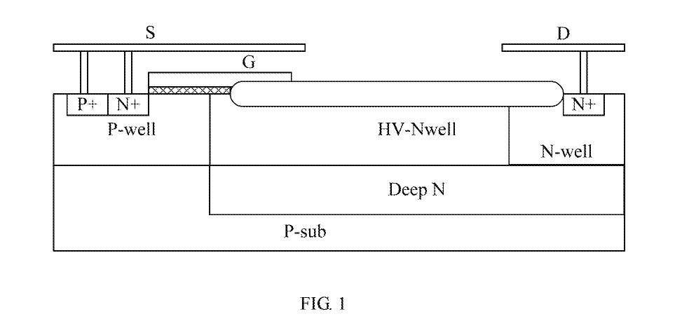

FIG. 2 is a perspective view of an N type lateral double-diffused metal oxide semiconductor field effect transistor according to an embodiment.

### DETAILED DESCRIPTION OF THE EMBODIMENTS

Embodiments of the invention are described more fully hereinafter with reference to the accompanying drawings, in which preferred embodiments of the invention are shown. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art.

In the specification and accompanying drawings, the reference signs N and P assigned to the layers or regions indicate that such layers or regions contains a large number of electrons or cavities. Further, reference signs + and − assigned to the N or P indicate that a concentration of dopant is greater or lower than a concentration in the layers without such signs. In the following description and accompanying drawing of the preferred embodiment, similar components aligned similar reference sings and redundant illustration is omitted herein.

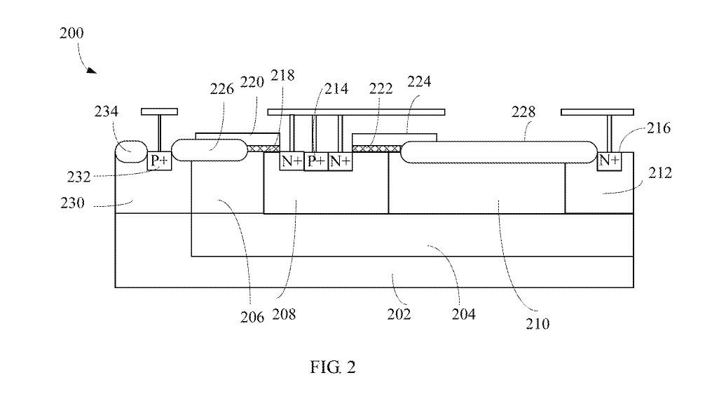

FIG. 2 is a perspective view of an N type lateral double-diffused metal oxide semiconductor field effect transistor according to an embodiment. The N type lateral double-diffused metal oxide semiconductor field effect transistor (NLDMOS) 200 includes a substrate 202; a first N well 204 formed on the substrate 202; a second N well 206, a first P well 208, a third N well 210 and a fourth N well 212 that are formed on a surface of the first N well 204; a source lead-out region 214 formed on the first P well 208; a drain lead-out region 216 formed on the fourth N well 212; a first gate lead-out region formed on surfaces of the second N well 206 and the first P well 208; and a second gate lead-out region formed on surfaces of the first P well 208 and the third N well 210. The first gate lead-out region and the second gate lead-out region are respectively led out by means of metal wires, and then are connected (not shown) to serve as a gate of the N type lateral double-diffused metal oxide semiconductor field effect transistor 200.

The substrate 202 is made of silicon, silicon carbide, gallium arsenide, indium phosphide or germanium-silicon. In the embodiment, the substrate 202 is a P type substrate which is made of silicon or contains silicon. In order to meet a requirement of a breakdown voltage of the high voltage N type lateral double-diffused metal oxide semiconductor field effect transistor 200, the substrate 202 is designed to have a greater specific resistance.

The first N well 204 is a deep N well region (i.e. the N+ type well), and the first N well 204 and the third N well 201 constitute a voltage withstanding drift region of the N type lateral double-diffused metal oxide semiconductor field effect transistor 200 together. The first N well 204 further serves as a second drift region of the N type lateral double-diffused metal oxide semiconductor field effect transistor 200, thereby improving a current capacity of the device. The first P well 208 is connected to the second N well 206 and the third N well 210: the third N well 210 is further connected to the fourth N well 212. The second N well is a low voltage N well, and serves as a portion of the first drift region of the N type lateral double-diffused metal oxide semiconductor field effect transistor 200, providing an electron collection function.

The first P well 208 mainly forms a channel region of the N type lateral double-diffused metal oxide semiconductor field effect transistor 200, and controls the break-over and turn-off of the device together with the gate. In the embodiment, because the gate includes a first gate lead-out region and a second gate lead-out region, therefore, the corresponding first P well 208 forms two channels on opposite sides of the source lead-out region 214 in the device. The third N well 210 is a high voltage N well, and constitutes the voltage withstanding drift region of the N type lateral double-diffused metal oxide semiconductor field effect transistor 200 together with the first N well 204.

The fourth N well 212 serves as a buffer layer of the N type lateral double-diffused metal oxide semiconductor field effect transistor 200 to provide a function for the conductive electron injection of device and the voltage withstand. An on-state voltage drop can be effectively reduced under the premise of ensuring a forward blocking voltage, by conducting a reasonable choice of a doping concentration and a thickness of the fourth N well 212. In the illustrated embodiment, the fourth N well 212 is a low voltage N well, the doping concentration therefore is greater than a doping concentration of the third N well 210, thus it can effectively avoid a depletion of the drain lead-out region 216 when the drain is connected to a high voltage.

The N type lateral double-diffused metal oxide semiconductor field effect transistor 200 further includes a first field oxide layer 226 formed on a surface of the second N well 206; and a second field oxide layer 228 formed on a surface of the third N well 210 and extending to a surface of the fourth N well 212. The first field oxide layer 226 and the second field oxide layer 228 both are made of silicon oxide, for example can be silicon dioxide. The first field oxide layer 226 and the second field oxide layer 228 serve as an isolation structure, configured to isolate the source structure from the drain structure, to reduce a leakage current between the source and the drain.

The first gate lead-out region includes a gate oxide layer 218 formed on a surface of the second N well 206 and extending to a surface (i.e. located between the first field oxide layer 226 and the source lead-out region 214) of the first P well 208; a polycrystalline silicon gate 220 on surfaces of the gate oxide layer 218 and the first field oxide layer 226. The second gate lead-out region includes a gate oxide layer 222 formed on a surface of the first P well 208 and extending to a surface (i.e. located between the source lead-out region 214 and the second field oxide layer 228) of the third N well 210; and a polycrystalline silicon gate 224 on surfaces of the gate oxide layer 222 and the second field oxide layer 228. The gate oxide layer 222 and the gate oxide layer 218 can be made of silicon oxide, for example can be silicon dioxide. In the embodiment, the source lead-out region 214 includes a first N type lead-out region, a second N type lead-out region, and a P type lead-out region. The first N type lead-out region and the second N type lead-out region are located on opposite sides of the P type lead-out region. The source lead-out region 214 is a P+ lead-out region, and serves as a source of the N type lateral double-diffused metal oxide semiconductor field effect transistor 200 after being led out by metal wires. The drain lead-out region 216 is a N+ lead-out region, and serves as a drain of the N type lateral double-diffused metal oxide semiconductor field effect transistor 200 after being led out by metal wires.

In the embodiment, the N type lateral double-diffused metal oxide semiconductor field effect transistor 200 further includes a second P well 230 formed on a surface of the substrate 202; a substrate lead-out region 232 located on the second P well 230, and a third field oxide layer 234 formed on a surface of the second P well 230. The second P well 230 is connected to the second N well 206. The second P well 230 is configured to lead out the substrate. The substrate lead-out region 232 is a P+ lead-out region, and serves as a bulk electrode, thereby forming a fourth terminal on the N type lateral double-diffused metal oxide semiconductor field effect transistor 200 in addition to the three terminals: the gate, the source, and the drain. The fourth terminal can modulate the N type lateral double-diffused metal oxide semiconductor field effect transistor 200 to operate. The third field oxide layer 234 serves as an isolation structure, and is configured to isolate the semiconductor device to isolate a surface leakage current, thereby avoiding occurring of occasions such as an turning on of the N type lateral double-diffused metal oxide semiconductor field effect transistor 200 without cause, due to the surface leakage current.

In above described N type lateral double-diffused metal oxide semiconductor field effect transistor 200, two channels are correspondingly formed on opposite right and left sides of the source lead-out region 214 by forming a first gate lead-out region and a second gate lead-out region. When the first gate lead-out region and the second gate lead-out region are connected to a high voltage (i.e. the gate is connected to a high voltage), the channels are switched on. When the drain lead-out region is connected to a high voltage, the carrier (electron) will flows toward the drain lead-out region (i.e. the drain terminal); one passes through the second N well 206 to flow downwardly toward the first N well 204, and then passes through the first N well 204 to flow toward the drain terminal; the other one passes through the third N well 210 and directly flows toward the drain terminal, thereby improving a current capacity of the device.

Above described N type lateral double-diffused metal oxide semiconductor field effect transistor 200 is provided with a first gate lead-out region and a second gate lead-out region, i.e. a gate lead-out region is added to the source terminal, thereby forming a new current channel by the second N well 206 and the first N well 204, which enables the current capacity to be doubled, and the current output capacity is relative greater while the area of the device almost does not increase.

Although the respective embodiments have been described one by one, it shall be appreciated that the respective embodiments will not be isolated. Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

The above are several embodiments of the present invention described in detail, and should not be deemed as limitations to the scope of the present invention. It should be noted that variations and improvements will become apparent to those skilled in the art to which the present invention pertains without departing from its spirit and scope. Therefore, the scope of the present invention is defined by the appended claims.

What is claimed is:

1. An N type lateral double-diffused metal oxide semiconductor field effect transistor, comprising:
a substrate;
a first N well formed on the substrate;
a second N well, a first P well, a third N well, and a fourth N well, all of which are formed on a surface of the first N well; wherein the first P well is connected to the second N well and the third N well, respectively; the third N well is connected to the fourth N well;
a source lead-out region formed on the first P well;
a drain lead-out region fanned on the fourth N well;
a first gate lead-out region formed on surfaces of the second N well and the first P well; and
a second gate lead-out region formed on surfaces of the first P well and the third N well;
wherein the first gate lead-out region and the second gate lead-out region are respectively led out by means of metal wire, and the first gate lead-out region and the second gate lead-out region are connected to serve as a gate of the N type lateral double-diffused metal oxide semiconductor field effect transistor.

2. The N type lateral double-diffused metal oxide semiconductor field effect transistor according to claim 1, wherein a doping concentration of the fourth N well is greater than a doping concentration of the third N well.

3. The N type lateral double-diffused metal oxide semiconductor field effect transistor according to claim 1, further comprising:
a first field oxide layer formed on a surface of the second N well; and
a second field oxide layer formed on a surface of the third N well and extending to a surface of the fourth N well.

4. The N type lateral double-diffused metal oxide semiconductor field effect transistor according to claim 3, wherein the first field oxide layer and the second field oxide layer are made of silicon nitride.

5. The N type lateral double-diffused metal oxide semiconductor field effect transistor according to claim 4, wherein the first gate lead-out region comprises:
a gate oxide layer fanned on a surface of the second N well and extending to a surface of the first P well, and
a polycrystalline silicon gate on surfaces of the gate oxide layer and the first field oxide layer;
wherein the second gate lead-out region comprises:
a gate oxide layer formed on a surface of the first P well and extending to a surface of the third N well; and
a polycrystalline silicon gate on surfaces of the gate oxide layer and the second field oxide layer.

6. The N type lateral double-diffused metal oxide semiconductor field effect transistor according to claim 4, further comprising:
a second P well formed on a surface of the substrate and connected to the second N well;
a substrate lead-out region located on the second P well; and
a third field oxide layer formed on a surface of the second P well; wherein the first field oxide layer extends to a surface of the second P well.

7. The N type lateral double-diffused metal oxide semiconductor field effect transistor according to claim 6, wherein the substrate lead-out region is a P type lead-out region.

8. The N type lateral double-diffused metal oxide semiconductor field effect transistor according to claim 1, wherein the drain lead-out region is an N type lead-out region.

9. The N type lateral double-diffused metal oxide semiconductor field effect transistor according to claim 1, wherein the source lead-out region comprises a first N type lead-out region, a second N type lead-out region, and a P type lead-out region; the first N type lead-out region and the second N type lead-out region are located on opposite sides of the P type lead-out region.

10. The N type lateral double-diffused metal oxide semiconductor field effect transistor according to claim 1, wherein the substrate is a P type substrate.
